(19) United States
(12) Patent Application Publication
(10) Pub. No.: US 2023/0049716 A1
(43) Pub. Date: Feb. 16, 2023

(54) ELECTRICAL OUTLET FOR POWER AND/OR DATA

(71) Applicant: Electracom Pty Ltd, Kings Park (AU)

(72) Inventor: James BAILEY, Kings Park (AU)

(21) Appl. No.: 17/818,755

(22) Filed: Aug. 10, 2022

(30) Foreign Application Priority Data
Aug. 13, 2021 (AU) 2021 902 522

(51) Int. Cl. H01R 13/514; H01R 13/518

(52) U.S. Cl. CPC H01R 13/514; H01R 13/518; H01R 2201/06

(57) ABSTRACT

An electrical outlet (10) for power and/or data is disclosed. The outlet 10 has a housing (11) which houses a plurality of moulded sub-components (18, 19) each of which is mounted within the housing (11) to have one or more sockets (8, 9) accessible by corresponding pin(s) of a plug used by a user. Not all of the sub-components (18, 19) are fabricated from the same mould. The sockets of the housed sub-components are covered by a cosmetic plate (17) having an array of openings corresponding to the sockets and sized to permit the pin(s) to pass through the openings and electrically engage the sockets. A method of fabricating such an electrical outlet is also disclosed. Preferably the outlet is authorised for sale and use without the cosmetic plate.

### FIELD OF THE INVENTION

The present invention relates to electrical outlets for power and/or data.

### BACKGROUND ART

Electrical outlets for power and/or data are widely used, particularly in modern offices where a wide range of electrical equipment is used. In particular, much of this electrical equipment is positioned on a user's desktop.

An example of such a desktop mounted electrical equipment is the power rail disclosed in Australian Patent Application No 2015 221 452 assigned to Assembly Electronics Pty Ltd. an associate of the present applicant. As seen in the drawings of that patent specification, the front face of the power rail is formed from an assembly of individually moulded electrical sub outlets. Some of these outlets have sockets for 240 V AC mains power whilst other of the outlets have sockets for USB chargers, and the like. As a consequence, each of the sub outlets which together constitute the power rail is required to be moulded in a different mould.

Even though the same plastic is utilised in the moulding, thereby ensuring that the colour of the front faces of the sub outlets is the same, because each mould has a slightly different finish, there is an observable difference between the front faces of each of the sub outlets. This detracts from the overall customer appeal of the power rail and makes it difficult for the power rail to be easily integrated into customer originated office decoration schemes.

### GENESIS OF THE INVENTION

The genesis of the present invention is a desire to remove, or substantially eliminate, such an observable difference and thereby enhance the customer appeal of the electrical outlets.

### SUMMARY OF THE INVENTION

In accordance with a first aspect of the present invention there is disclosed an electrical outlet for power and/or data having a housing which houses a plurality of moulded sub-components each of which is mounted within said housing to have one or more sockets accessible by corresponding pin(s) of a plug used by a user, and not all of said sub-components are fabricated from the same mould, wherein said sockets of said housed sub-components are covered by a cosmetic plate having an array of openings corresponding to said sockets and sized to permit said pin(s) to pass through said openings and electrically engage said sockets.

In accordance with a second aspect of the present invention there is disclosed a method of fabricating a multi-socket electrical outlet having a housing which houses a plurality of moulded sub-components, each of which is mounted within said housing to have one or more sockets accessible by corresponding pin(s) of a plug used by a user, said method including the steps of:

covering said one or more sockets by a cosmetic plate having an array of openings corresponding to said sockets and sized to permit said pin(s) pass through said openings and electrically engage said sockets, and

selecting the colour of said cosmetic plate from a range of colours.

Preferably, the multi-socket electrical outlet is authorised to use without the cosmetic plate.

### BRIEF DESCRIPTION OF THE DRAWINGS

A preferred embodiment of the invention will now be described, by way of example only, with reference to the accompanying drawings in which:

FIG. 1 is a perspective view of a multi-socket outlet of a first embodiment of the present invention,

FIG. 2 is a perspective view of a socket outlet, similar to FIG. 1, and showing in exploded fashion the application of a cosmetic plate,

FIG. 3 is a perspective view showing the peeling away of a cover sheet so as to expose the adhesive coated rear surface of the cosmetic plate,

FIG. 4 is a perspective view of a multi-socket outlet of another embodiment having a different socket configuration, and

FIG. 5 is a perspective view of a multi-socket outlet of a still further embodiment having a different exterior housing configuration.

### DETAILED DESCRIPTION

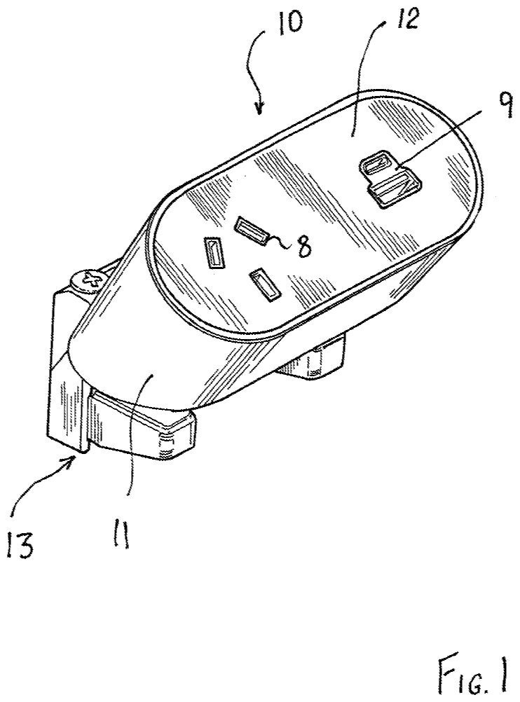

As seen in FIG. 1, a multi-socket electrical outlet 10 has a housing 11 with a front face 12 and a clamp mechanism 13 which permits the outlet 10 to be clamped to a conventional desktop (not illustrated). Located in the front face 12 is an electrical outlet 8 for a three pin socket for mains voltage (e.g. 240 V AC) use and a USB socket 9. As is well known, the three pin socket outlet 8 cooperates with either a two pin or a three pin male 240 V AC plug whilst the USB socket 9 cooperates with a male single pin USB plug.

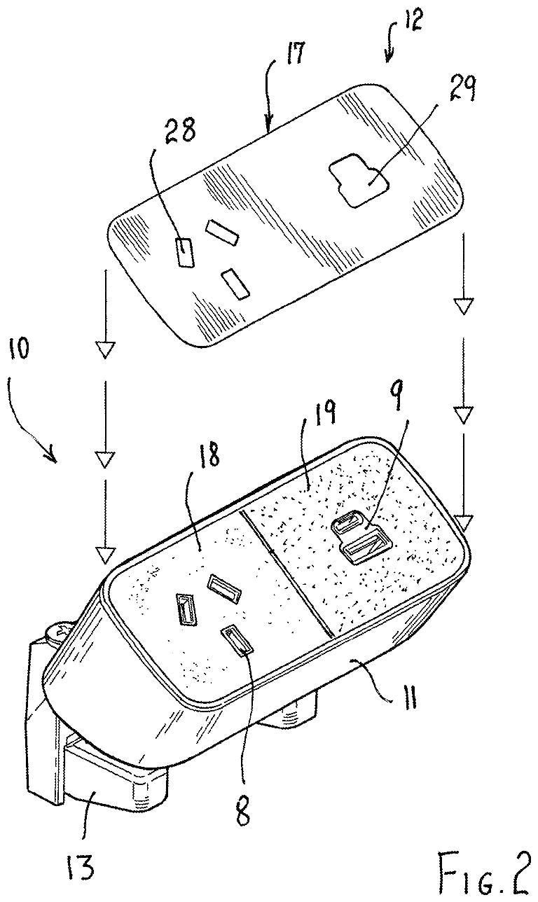

As seen in FIG. 2, the front face 12 is formed from a cosmetic plate 17 which covers two mouldings 18 and 19. Moulding 18 is formed from a first mould (not illustrated but conventional) and contains the three pin socket outlet 8. Moulding 19 is formed from a second mould (also not illustrated but conventional) and contains the USB outlet 9. Although the plastic used in each of mouldings 18 and 19 is the same, because of slight differences in the surface finishing of the mould interiors, there is a discernible difference in appearance between the mouldings 18 and 19 and this is illustrated in FIG. 2 by a different density of dots. It is difficult and time-consuming to address this difference in appearance by attempting to polish, or burnish, or otherwise treat the mould interiors.

In accordance with the preferred embodiment, the front face of each of the mouldings 18, 19 is covered by means of the cosmetic plate 17 which has an array of openings 28, 29 which corresponds to the position, size, shape and orientation of the sockets 8 and 9, thereby enabling the plug pin(s) to pass through the openings 28,29 and engage with the sockets 8,9.

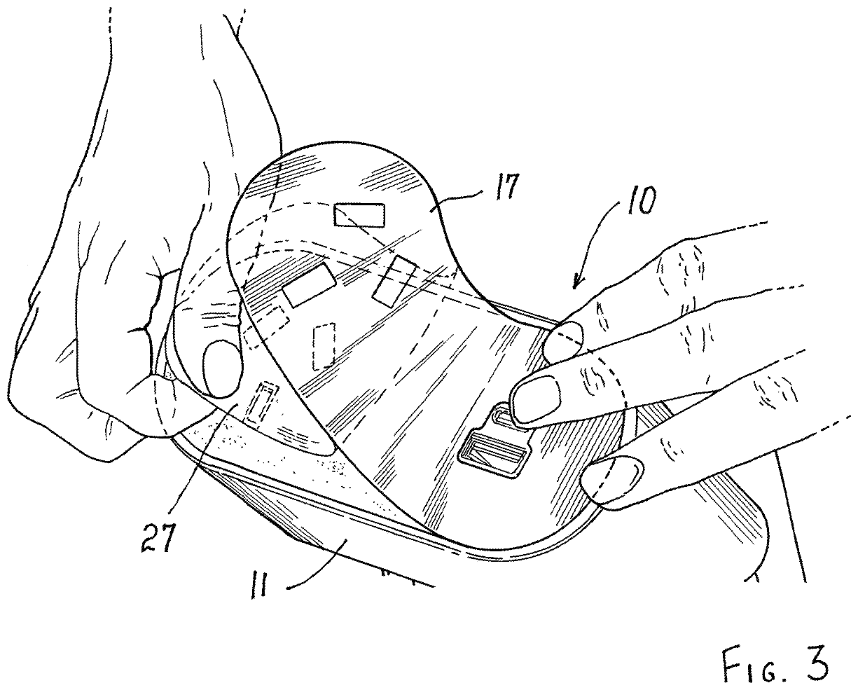

As seen in FIG. 3, the cosmetic plate 17 is preferably formed as a flexible sheet having an adhesive rear surface which is covered by a cover sheet 27 which can be peeled away so as to reveal the virgin adhesive surface. This virgin adhesive surface is applied to the front faces of the mouldings 18-19 so as to produce the finished product illustrated in FIG. 1.

It is well-known that electrical outlets require authorisation from an authorising body before they are sold or used in Australia, and other jurisdictions. In order to guard against the possible loss of the cosmetic plate 17, the multi-socket outlet 10 of the preferred embodiment is designed to achieve product sale authorisation from the relevant authorising body without the cosmetic plate 17. Therefore, the overall arrangement is safe, even if the cosmetic plate 17 should eventually be dislodged or removed during use.

Furthermore, the cosmetic plate 17 is fabricated from a single sheet of plastic either by stamping, or by moulding, and therefore has a uniform appearance which is easily achieved. In addition, a wide range of colours and textures, if upholstered, for example, are able to be achieved in order to cooperate with any interior colour scheme designed by the office inhabitants.

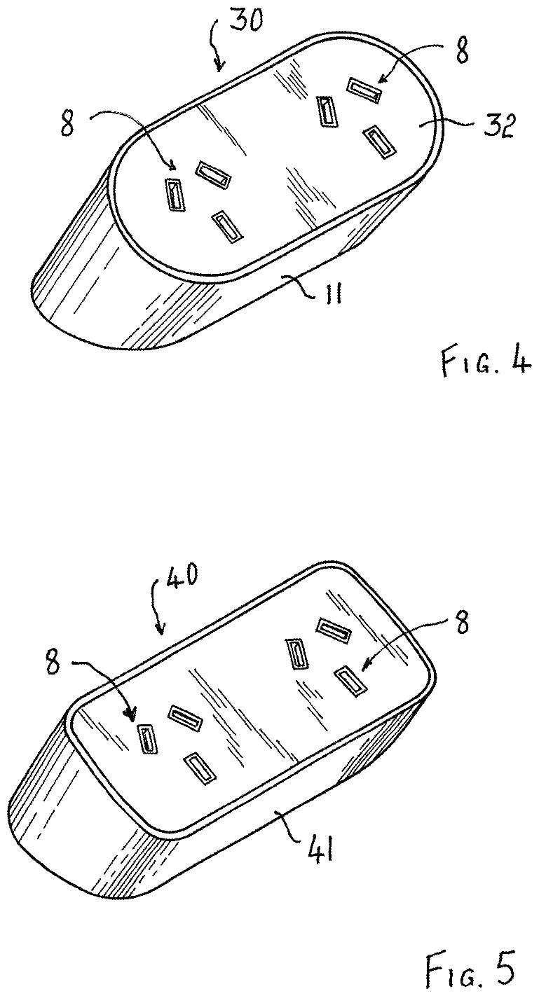

As seen in FIG. 4, the front face 32 of a multi-socket outlet 30 having a housing with a generally oval figuration, can be provided with other socket configurations, such as two 240 V AC sockets 8, if desired. Similarly, as seen in FIG. 5, a multi-socket outlet 40 can be provided with a housing 41 of a generally rectangular configuration. It will be apparent that the overall configuration of FIGS. 1, 3 and 4 and the rectangular configuration of FIGS. 2 and 5 provide a wide range of attributes within a single product range.

The foregoing describes only some embodiments of the present invention and modifications, obvious to those skilled in the electrical arts, can be made thereto without departing from the scope of the present invention.

The term “comprising” (and its grammatical variations) as used herein is used in the inclusive sense of “including” or “having” and not in the exclusive sense of “consisting only of”.

1. An electrical outlet for power and/or data having a housing which houses a plurality of moulded sub-components each of which is mounted within said housing to have one or more sockets accessible by corresponding pin(s) of a plug used by a user, and not all of said sub-components are fabricated from the same mould, wherein said sockets of said housed sub-components are covered by a cosmetic plate having an array of openings corresponding to said sockets and sized to permit said pin(s) to pass through said openings and electrically engage said sockets.

2. The electrical outlet as claimed in claim 1 wherein said outlet is authorised for sale and use without said cosmetic plate.

3. The electrical outlet as claimed in claim 1 wherein said cosmetic plate completely covers said front faces.

4. The electrical outlet is as claimed in claim 1 wherein said cosmetic plate is flexible.

5. The electrical outlet as claimed in claim 1 wherein said sockets are selected from the class consisting of mains frequency AC sockets and USB sockets.

6. The electrical outlet as claimed in claim 1 wherein said cosmetic plate is adhered to a front face of each of said mouldings.

7. A method of fabricating a multi-socket electrical outlet having a housing which houses a plurality of moulded sub-components, each of which is mounted within said housing to have one or more sockets accessible by corresponding pin(s) of a plug used by a user, said method including the steps of:
covering said one or more sockets by a cosmetic plate having an array of openings corresponding to said sockets and sized to permit said pin(s) pass through said openings and electrically engage said sockets, and
selecting the colour of said cosmetic plate from a range of colours.

8. The method as claimed in claim 7 including the further step of authorising said electrical outlet for sale and use without said cosmetic plate.

9. The method as claimed in claim 7 including the step of completely covering said front faces with said cosmetic plate.

10. The method as claimed in claim 7 wherein said cosmetic plate is flexible.

11. The method as claimed in claim 7 including the further step of selecting said sockets from the class consisting of mains frequency AC sockets and USB sockets.

12. The method as claimed in claim 7 including the further step of adhering said cosmetic plate is to a front face of each of said mouldings.
